(19) United States
(12) Patent Application Publication
(10) Pub. No.: US 2016/0300625 A1
(43) Pub. Date: Oct. 13, 2016

(54) SEMICONDUCTOR APPARATUS AND TEST METHOD THEREOF

(71) Applicant: SK hynix Inc., Icheon-si Gyeonggi-do (KR)

(72) Inventor: Min Chang KIM, Icheon-si Gyeonggi-do (KR)

(21) Appl. No.: 14/742,956

(22) Filed: Jun. 18, 2015

(30) Foreign Application Priority Data
Apr. 10, 2015 (KR) 10-2015-0051049

(51) Int. Cl. G11C 29/12; G11C 7/10; G11C 7/22

(52) U.S. Cl. CPC G11C 29/1201; G11C 7/22; G11C 7/106; G11C 7/1057

(57) ABSTRACT

A semiconductor apparatus may include a first data processing block electrically coupled between a first input/output pad array and a first memory array. The semiconductor apparatus may include a second data processing block electrically coupled between a second input/output pad array and a second memory array. The first test verification data and second test verification data may be generated by causing data to be respectively outputted from the first memory array and the second memory array to pass through the first data processing block and the second data processing block, according to a read command and a plurality of control signals. The first test verification data and the second test verification data may be respectively written again in the first memory array and the second memory array. A result of comparing the first test verification data and the second test verification data may be outputted through the first input/output pad array.

### CROSS-REFERENCES TO RELATED APPLICATION

The present application claims priority under 35 U.S.C. §119(a) to Korean application number 10-2015-0051049, filed on Apr. 10, 2015, in the Korean Intellectual Property Office, which is incorporated herein by reference in its entirety.

### BACKGROUND

1. Technical Field

Various embodiments generally relate to a semiconductor circuit, and more particularly, to a semiconductor apparatus and a test method of the semiconductor apparatus.

2. Related Art

Referring to FIG. 1, a semiconductor apparatus 10 according to the conventional art consists of a first memory array 11, a first data processing block 21, and a first input/output pad array 41. The semiconductor apparatus 10 also consists of a second memory array 12, a second data processing block 31, and a second input/output pad array 42.

The first memory array 11 and the second memory array 12 configure one memory block, for example, a bank. The first memory array 11 and the second memory array 12 are half banks, respectively.

The first data processing block 21 is electrically coupled with the first memory array 11 through input/output lines. The input/.output lines electrically coupled with the first memory array 11 are first global input/output line group GIO<0:63>. The first data processing block 21 processes data according to respective read/write operations.

The first data processing block 21 consists of a read circuit unit 22 and a write circuit unit 23.

The first data processing block 21 is electrically coupled with a tester 51 through the first input/output pad array 41.

The second data processing block 31 is electrically coupled with the second memory array 12 through a second global input/output line group GIO<64:127>, and processes data according to respective read/write operations.

The second data processing block 31 consists of a read circuit unit 32 and a write circuit unit 33.

The second data processing block 31 is electrically coupled with a tester 52 through the second input/output pad array 42.

The first data processing block 21 and the second data processing block 31 consist within peripheral circuits which are associated with the input/output of data in the semiconductor apparatus 10.

In order to process a total of 32-bit data D<0:15> and D<16:31>, the semiconductor apparatus 10 consists of a total of 32 pads with 16 pads disposed in each of the first input/output pad array 41 and the second input/output pad array 42.

However, in the conventional art, due to the limited number of the channels of a tester, a test cannot help but be performed by electrically coupling the different testers 51 and 52 to the first input/output pad array 41 and the second input/output pad array 42, respectively. As a consequence, test efficiency may deteriorate and costs may increase, which is problematic.

### SUMMARY

According to an embodiment, there may be provided a semiconductor apparatus. The semiconductor apparatus may include a first data processing block electrically coupled between a first input/output pad array and a first memory array. The semiconductor apparatus may include a second data processing block electrically coupled between a second input/output pad array and a second memory array. The first test verification data and second test verification data may be generated by causing data to be respectively outputted from the first memory array and the second memory array to pass through the first data processing block and the second data processing block, according to a read command and a plurality of control signals. The first test verification data and the second test verification data may be respectively written again in the first memory array and the second memory array. A result of comparing the first test verification data and the second test verification data may be outputted through the first input/output pad array.

According to an embodiment, there may be provided a semiconductor apparatus. The semiconductor apparatus may include a first data processing block electrically coupled between a first input/output pad array and a first memory array, and may be configured to write data outputted from the first memory array, in the first memory array as first test verification data in response to a plurality of control signals during a read operation. The semiconductor apparatus may include a second data processing block electrically coupled between a second input/output pad array and a second memory array, and may be configured to write data outputted from the second memory array, in the second memory array as second test verification data in response to the plurality of control signals during the read operation. The semiconductor apparatus may include a copy unit configured to copy data to be written in the first memory array according to a write command, and may write the copied data in the second memory array. The semiconductor apparatus may include a comparison unit configured to output a result of comparing the first test verification data and the second test verification data, through the first input/output pad array.

According to an embodiment, there may be provided a semiconductor apparatus. The semiconductor apparatus may include an input/output pad array, and a memory array. The semiconductor apparatus may include a read circuit unit configured to perform a read-associated operation for outputting data outputted from the memory array, to the input/output pad array in a read operation. The semiconductor apparatus may include a write circuit unit configured to perform a write-associated operation for inputting data inputted through the input/output pad array, to the memory array in a write operation. The write circuit unit may be configured to input data outputted to the input/output pad array via the read circuit unit in the read operation, to the memory array according to a plurality of control signals.

### BRIEF DESCRIPTION OF THE DRAWINGS

FIG. 1 is a diagram illustrating the configuration of a semiconductor apparatus 10 according to the conventional art.

FIG. 2 is a diagram illustrating a representation of an example of the configuration of a semiconductor apparatus 100 in accordance with an embodiment.

FIG. 3 is a diagram illustrating a representation of an example of the configuration of a semiconductor apparatus 101 in accordance with an embodiment.

FIG. 4 is a diagram illustrating a representation of an example of the internal configuration of the write circuit unit 231 illustrated in FIG. 3.

FIG. 5 is a diagram illustrating a representation of an example of the internal configuration of the control signal generation unit 900 illustrated in FIG. 3.

FIG. 6 is a representation of an example of a timing diagram to assist in the explanation of a method for testing a semiconductor apparatus in accordance with an embodiment.

FIG. 7 illustrates a block diagram of an example of a representation of a system employing a semiconductor apparatus and/or test method of the semiconductor apparatus in accordance with the various embodiments discussed above with relation to FIGS. 2-6.

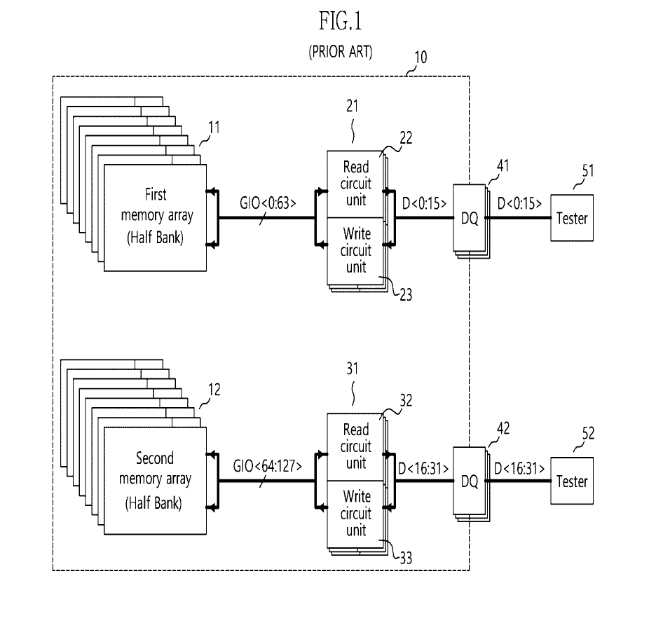

### DETAILED DESCRIPTION

Hereinafter, a semiconductor apparatus and a test method thereof will be described below with reference to the accompanying drawings through various examples of embodiments.

Various embodiments may be directed to a semiconductor apparatus and a test method of the semiconductor apparatus capable of improving test efficiency and saving costs.

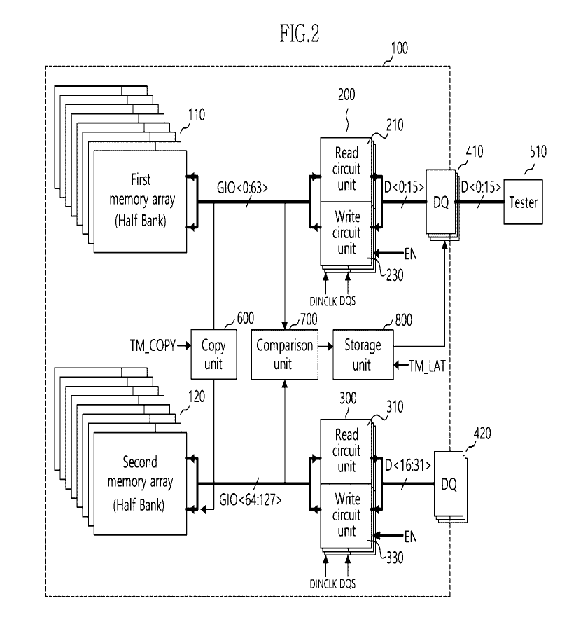

Referring to FIG. 2, a semiconductor apparatus 100 in accordance with an embodiment may include a first memory array 110, a first data processing block 200, and a first input/output pad array 410. The semiconductor apparatus 100 may include a second memory array 120, a second data processing block 300, and a second input/output pad array 420. The semiconductor apparatus 100 may include a copy unit 600, a comparison unit 700, and a storage unit 800.

The first memory array 110 and the second memory array 120 may configure one memory block, for example, a bank. The first memory array 110 and the second memory array 120 may be half banks, respectively.

The first data processing block 200 may be electrically coupled with the first memory array 110 through input/output lines, for example, a first global input/output line group GIO<0:63>. The first data processing block 200 may process data according to respective read/write operations.

The first data processing block 200 may include a read circuit unit 210 and a write circuit unit 230.

The write circuit unit 230 may process data according to the write operation. The write circuit unit 230 may process the data according to the write operation, in response to a plurality of control signals, for example but not limited to, EN, DQS and DINCLK.

Among the plurality of control signals EN, DQS and DINCLK, EN may be a signal enabled during the write operation period of the semiconductor apparatus 100, DQS may be a data strobe signal, and DINCLK may be a data input clock signal.

The second data processing block 300 may be electrically coupled with the second memory array 120 through a second global input/output line group GIO<64:127>. The second data processing block 300 may process data according to respective read/write operations.

The second data processing block 300 may include a read circuit unit 310 and a write circuit unit 330.

The write circuit unit 330 may process data according to the write operation. The write circuit unit 330 may process data according to the write operation in response to the plurality of control signals EN, DQS and DINCLK.

In an embodiment, the first data processing block 200 and the second data processing block 300 may be included in peripheral circuits associated with the input/output of data in the semiconductor apparatus 100.

In order to process a total of 32-bits of data D<0:15> and D<16:31>, the semiconductor apparatus 100 may include a total of 32 pads with 16 pads disposed in the first input/output pad array 410 and 16 pads disposed in the second input/output pad array 420.

A tester 510 may be electrically coupled to either the first input/output pad array 410 or the second input/output pad array 420. For example, the tester 510 may be electrically coupled to the first input/output pad array 410.

The copy unit 600 may copy the data transmitted through the first global input/output line group GIO<0:63> in response to a second test mode signal TM_COPY, and transmit the copied data to the second memory array 120.

The comparison unit 700 may perform a comparison, for example, compression/comparison, of the data transmitted through the first global input/output line group GIO<0:63> and the data transmitted through the second global input/output line group GIO<64:127>, and output a comparison result.

The storage unit 800 may latch the output of the comparison unit 700 according to a third test mode signal TM_LAT, and output the latched output to an exterior of the semiconductor apparatus 100 through the first input/output pad array 410.

A test method of the semiconductor apparatus 100 in accordance with an embodiment, configured as mentioned above, will be described below.

First, the tester 510 provides a write command, test data and the control signal DQS to the semiconductor apparatus 100 with predetermined timing.

Also, the tester 510 provides the second test mode signal TM_COPY to the semiconductor apparatus 100 with predetermined timing.

According to the write command, the control signal EN is enabled.

The write circuit unit 230 writes the test data in the first memory array 110 through the first global input/output line group GIO<0:63> according to the plurality of control signals EN, DQS and DINCLK.

The copy unit 600 copies the data transmitted through the first global input/output line group GIO<0:63> according to the second test mode signal TM_COPY, and writes the copied data in the second memory array 120.

Thereafter, the tester 510 provides a read command and the third test mode signal TM_LAT to the semiconductor apparatus 100 with predetermined timing.

According to the read command, the data written during the write operation are outputted from the first memory array 110 and the second memory array 120, respectively.

The comparison unit 700 compresses and compares the data respectively outputted from the first memory array 110 and the second memory array 120, and outputs a comparison result.

The storage unit 800 latches the output signal of the comparison unit 700 according to the third test mode signal TM_LAT, and transmits the latched output signal to the tester 510 through the first input/output pad array 410.

The tester 510 may check whether the data write operation and the data read operation are normally performed in the semiconductor apparatus 100, according to the output signal of the storage unit 800.

The semiconductor apparatus 100 in accordance with an embodiment may perform an operation test by electrically coupling the tester 510 to either the first input/output pad array 410 or the second input/output pad array 420 for processing the total 32-bit data D<0:15> and D<16:31>.

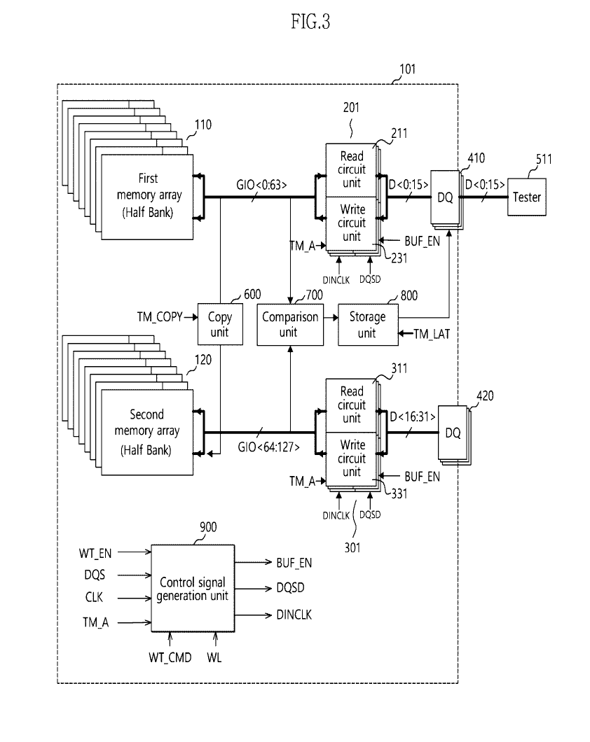

Referring to FIG. 3, a semiconductor apparatus 101 in accordance with an embodiment may include a first memory array 110, a first data processing block 201, and a second memory array 120. The semiconductor apparatus 101 may include a second data processing block 301, a first input/output pad array 410, and a second input/output pad array 420. The semiconductor apparatus 101 may include a copy unit 600, a comparison unit 700, a storage unit 800, and a control signal generation unit 900.

The first memory array 110 and the second memory array 120 may configure one memory block, for example, a bank. The first memory array 110 and the second memory array 120 may be half banks, respectively.

The first data processing block 201 may be electrically coupled with the first memory array 110 through input/output lines, for example, a first global input/output line group GIO<0:63>, and may process data according to respective read/write operations.

The first data processing block 201 may include a read circuit unit 211 and a write circuit unit 231.

The write circuit unit 231 may process data according to the write operation, in response to first to third control signals BUF_EN, DQSD and DINCLK and a first test mode signal TM_A.

The first control signal BUF_EN may be a signal enabled during the write operation period of the semiconductor apparatus 101 and the enable period of the first test mode signal TM_A.

The second control signal DQSD may be a signal generated by delaying a data strobe signal DQS by a predetermined time.

The third control signal DINCLK may be a data input clock signal.

In an embodiment, during a test mode, the write circuit unit 231 processes data according to the read operation but not the write operation.

For example, the write circuit unit 231 performs an operation of writing again, not the data inputted through the first input/output pad array 410 according to the write operation, but the data outputted from the read circuit unit 211 according to the read operation, in the first memory array 110, as first test verification data.

The second data processing block 301 may be electrically coupled with the second memory array 120 through a second global input/output line group GIO<64:127>. The second data processing block 301 may process data according to respective read/write operations.

The second data processing block 301 may include a read circuit unit 311 and a write circuit unit 331.

The write circuit unit 331 may process data according to the write operation. The write circuit unit 331 may process the data according to the write operation in response to the first to third control signals BUF_EN, DQSD and DINCLK and the first test mode signal TM_A.

In an embodiment, during the test mode, the write circuit unit 331 processes data according to the read operation but not the write operation.

For example, the write circuit unit 331 performs an operation of writing again, not the data inputted through the second input/output pad array 420 according to the write operation, but the data outputted from the read circuit unit 311 according to the read operation, in the first memory array 120, as second test verification data.

The first data processing block 201 and the second data processing block 301 may be included in peripheral circuits associated with the input/output of data in the semiconductor apparatus 101.

In order to process a total of 32-bits of data D<0:15> and D<16:31>, the semiconductor apparatus 101 may include a total of 32 pads with 16 pads disposed in the first input/output pad array 410 and 16 pads disposed in the second input/output pad array 420.

A tester 511 may be electrically coupled to either the first input/output pad array 410 or the second input/output pad array 420. For example, the tester 511 may be electrically coupled to the first input/output pad array 410.

The copy unit 600 may copy the data transmitted through the first global input/output line group GIO<0:63> in response to a second test mode signal TM_COPY, and transmit the copied data to the second memory array 120.

The comparison unit 700 may perform a comparison, for example, compression/comparison, of the data transmitted through the first global input/output line group GIO<0:63> and the data transmitted through the second global input/output line group GIO<64:127>, and output a comparison result.

The storage unit 800 may latch the output of the comparison unit 700 according to a third test mode signal TM_LAT, and output the latched output to the tester 511 through the first input/output pad array 410.

The control signal generation unit 900 may generate the first to third control signals BUF_EN, DQSD and DINCLK according to a write enable signal WT_EN, the data strobe signal DQS, the first test mode signal TM_A, a clock signal CLK, a write command signal WT_CMD, and a write latency WL.

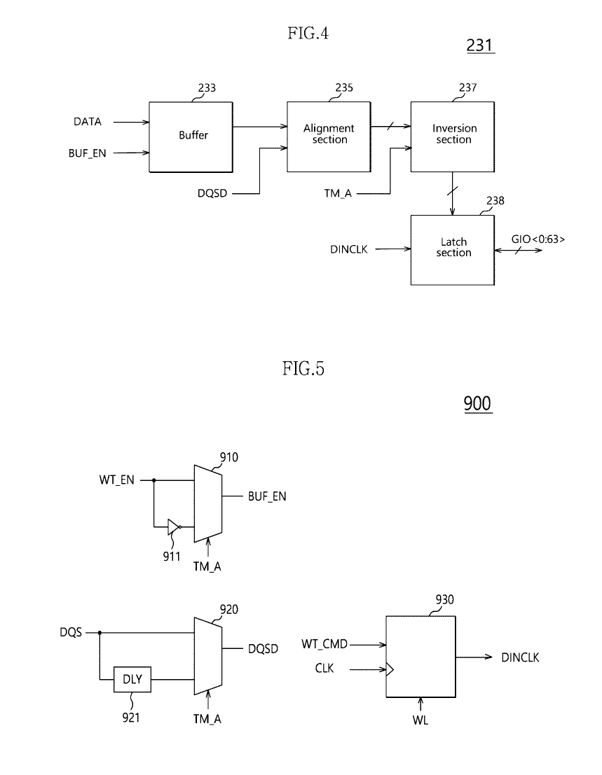

Referring to FIG. 4, the write circuit unit 231 may include a buffer 233, an alignment section 235, an inversion section 237, and a latch section 238.

The buffer 233 may be inputted with data DATA during the enable period of the first control signal BUF_EN.

The alignment section 235 may align the output signal of the buffer 233, that is, serial data, as parallel data in response to the second control signal DQSD, and output the parallel data.

The inversion section 237 may invert the output signal of the alignment section 235 and output a resultant signal, in the example where the first test mode signal TM_A is enabled.

In the example where the first test mode signal TM_A is enabled, that is, while the test mode proceeds by electrically coupling the tester 511, the write circuit unit 231 performs an operation of writing the same data as data in the read operation.

In other words, the write circuit unit 231 performs the operation of writing again not the data inputted through the first input/output pad array 410 according to the write operation but the data outputted from the read circuit unit 211 according to the read operation, in the first memory array 110.

In this example, even though the write operation is not normally performed due to the fail of the write circuit unit 231, an example may occur, in which it is impossible to determine whether the semiconductor apparatus 101 normally operates or not, since a result of comparing the data on the first global input/output line group GIO<0:63> and the data on the second global input/output line group GIO<64:127> according to the read operation performed before the write operation is transmitted to the tester 511.

Therefore, by inverting the output signal of the alignment section 235 through using the inversion section 237, it may be possible to reflect whether the write circuit unit 231 is normally operating or not, for a test.

The latch section 238 may latch the output signal of the inversion section 237 in response to the third control signal DINCLK. The latch section 238 may transmit the latched output signal to the first memory array 110 through the first global input/output line group GIO<0:63>.

Referring to FIG. 5, the control signal generation unit 900 may include first and second multiplexers 910 and 920, and an inverter 911. The control signal generation unit 900 may include a delay (DLY) 921, and a shift section 930.

The inverter 911 may invert the write enable signal WT_EN, and output the inverted signal of the write enable signal WT_EN.

The first multiplexer 910 may select the write enable signal WT_EN or the output signal of the inverter 911 according to the first test mode signal TM_A, and output the first control signal BUF_EN.

The write enable signal WT_EN may be a signal enabled during the write operation period and may be disabled during a period except the write operation period.

The first multiplexer 910 may output the first control signal BUF_EN by selecting the output signal of the inverter 911, in the example where the first test mode signal TM_A is enabled.

During a read operation period, the write enable signal WT_EN may retain a disabled state, for example, a low level, and the inverter 911 may output a signal of a high level.

Accordingly, the first multiplexer 910 may enable the first control signal BUF_EN to a high level in the example where the first test mode signal TM_A is enabled.

The delay 921 may delay the data strobe signal DQS by the predetermined time, and output the delayed data strobe signal DQS.

During the write operation, the alignment section 235 of FIG. 4 may operate according to the data strobe signal DQS provided from an exterior, for example, the tester 511.

During the read operation, the tester 511 may not provide the data strobe signal DQS.

Therefore, during the read operation, the write circuit unit 231 should use the data strobe signal DQS generated internally of the semiconductor apparatus 101, by controlling the setup/hold margins thereof.

The setup/hold margins of the data strobe signal DQS may be controlled through the delay 921.

The second multiplexer 920 may select the data strobe signal DQS or the output signal of the delay 921 according to the first test mode signal TM_A, and output the second control signal DQSD.

The second multiplexer 920 may output the output signal of the delay 921 as the second control signal DQSD in the example where the first test mode signal TM_A is enabled.

The second multiplexer 920 may output the data strobe signal DQS as the second control signal DQSD in the example where the first test mode signal TM_A is disabled.

The shift section 930 may shift the write command signal WT_CMD by the write latency WL based on the clock signal CLK, and output the third control signal DINCLK.

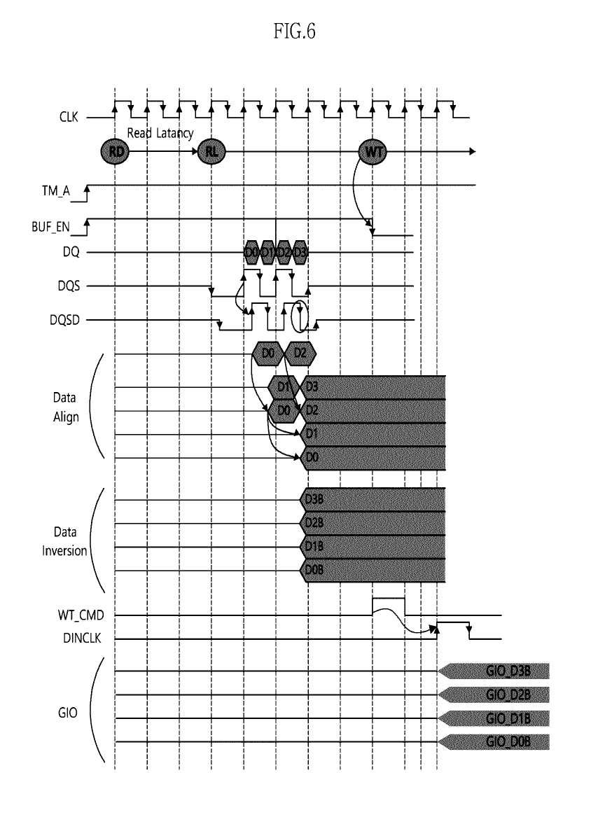

An example of a test method of the semiconductor apparatus 101 in accordance with an embodiment, configured, for example, as mentioned above (i.e., see FIGS. 2-5), will be described below with reference to FIG. 6.

First, while not illustrated in FIG. 6, the tester 511 may provide a write command and the second test mode signal TM_COPY to the semiconductor apparatus 101 with predetermined timing, such that the same test data may be written in the first memory array 110 and the second memory array 120 by the write circuit unit 231 and the copy unit 600.

The tester 511 enables the first test mode signal TM_A.

As the first test mode signal TM_A is enabled, the first control signal BUF_EN is enabled.

The tester 511 provides a read command RD to the semiconductor apparatus 101.

The data having been written in the first memory array 110 and the second memory array 120 are outputted to the first input/output pad array 410 and the second input/output pad array 420 through the read circuit units 211 and 311 according to the read command RD.

Since the first control signal BUF_EN is in the enabled state, the data outputted to the first input/output pad array 410 and the second input/output pad array 420 through the read circuit units 211 and 311 are inputted to the write circuit units 231 and 331.

After a read latency RL passes from when the read command RD is inputted, the write circuit units 231 and 331 perform data alignment and data inversion according to the second control signal DQSD.

The tester 511 provides a write command WT to the semiconductor apparatus 101.

The write command signal WT_CMD is generated according to the write command WT.

As the write command signal WT_CMD is shifted by the write latency WL, the third control signal DINCLK is generated.

The write circuit units 231 and 331 transmit the first test verification data and the second test verification data having undergone the data alignment (i.e., D0-D3) and the data inversion (i.e., D0B-D3B) to the first global input/output line group GIO<0:63> and the second global input/output line group GIO<64:127> (i.e. GIO_D0B-GIO_D3B) according to the third control signal DINCLK.

Thereafter, the tester 511 provides the third test mode signal TM_LAT to the semiconductor apparatus 101 with predetermined timing.

The comparison unit 700 compresses and compares the first test verification data and the second test verification data transmitted to the first global input/output line group GIO<0:63>and the second global input/output line group GIO<64:127>, and outputs a comparison result.

The storage unit 800 latches the output signal of the comparison unit 700 according to the third test mode signal TM_LAT, and transmits the latched output signal to the tester 511 through the first input/output pad array 410.

The tester 511 may check whether the data write operation and the data read operation are normally performed in the semiconductor apparatus 101, according to the output signal of the storage unit 800.

As described above, the semiconductor apparatus 101 in accordance with an embodiment may perform an operation test by electrically coupling the tester 511 to either the first input/output pad array 410 or the second input/output pad array 420 for processing the total 32-bit data D<0:15>and D<16:31>.

Also, it may be possible to check whether the entire semiconductor apparatus 101 including peripheral circuit configurations not coupled with the tester 511, that is, the read circuit unit 311 and the write circuit unit 331 coupled with the second input/output pad array 420, are normally operating or not.

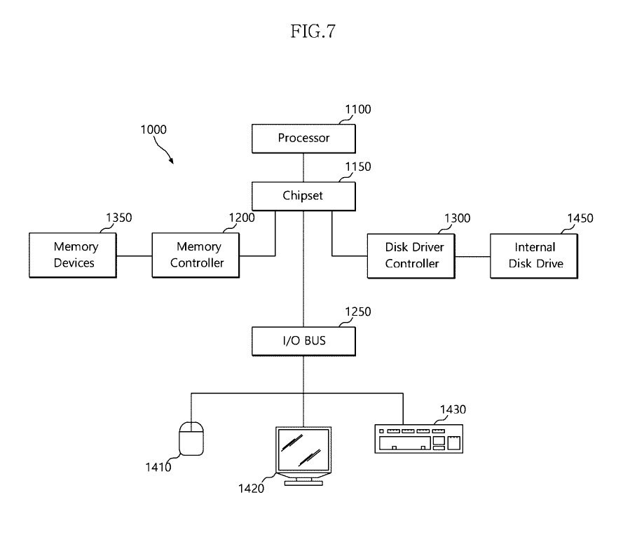

The semiconductor apparatuses and/or test methods of the semiconductor apparatuses discussed above (see FIGS. 2-6) are particular useful in the design of memory devices, processors, and computer systems. For example, referring to FIG. 7, a block diagram of a system employing a semiconductor apparatus and/or test method of the semiconductor apparatus in accordance with the various embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one semiconductor apparatus and/or test method of the semiconductor apparatus as discussed above with reference to FIGS. 2-6. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor apparatus and/or test method of the semiconductor apparatus as discussed above with relation to FIGS. 2-6, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250.

The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 7 is merely one example of a system employing a semiconductor apparatus and/or test method of the semiconductor apparatus as discussed above with relation to FIGS. 2-6. In alternate embodiments, such as cellular phones or digital cameras, the components may differ from the embodiments illustrated in FIG. 7.

While various embodiments have been described above, it will be understood to those skilled in the art that the embodiments described are examples only. Accordingly, the semiconductor apparatus and the test method thereof described herein should not be limited based on the described embodiments.

What is claimed is:

1. A semiconductor apparatus comprising:
a first data processing block coupled between a first input/output pad array and a first memory array; and
a second data processing block coupled between a second input/output pad array and a second memory array,
wherein first test verification data and second test verification data are generated by causing data to be respectively outputted from the first memory array and the second memory array to pass through the first data processing block and the second data processing block, according to a read command and a plurality of control signals, and the first test verification data and the second test verification data are respectively written again in the first memory array and the second memory array, and
wherein a result of comparing the first test verification data and the second test verification data is outputted through the first input/output pad array.

2. The semiconductor apparatus according to claim 1, further comprising:
a storage unit configured to store the result of comparing the first test verification data and the second test verification data.

3. The semiconductor apparatus according to claim 1,
wherein the first data processing block comprises a read circuit unit and a write circuit unit, and
wherein the write circuit unit is configured to receive data outputted to the first input/output pad array via the read circuit unit according to the read command, according to any one among the plurality of control signals, and the write circuit unit is configured to output the received data to the first memory array according to another one among the plurality of control signals.

4. The semiconductor apparatus according to claim 3,
wherein the plurality of control signals include a control signal, a data strobe signal, and a data input clock signal, and
wherein the control signal of the plurality of control signals is enabled during a write operation period of the semiconductor apparatus.

5. The semiconductor apparatus according to claim 1, further comprising:
a control signal generation unit configured to generate the plurality of control signals in response to a write enable signal and a data strobe signal.

6. The semiconductor apparatus according to claim 1, further comprising:
a control signal generation unit configured to generate any one among the plurality of control signals in response to a test mode signal and a write enable signal, and generate another one among the plurality of control signals in response to the test mode signal and a data strobe signal.

7. The semiconductor apparatus according to claim 1, further comprising:
a control signal generation unit configured to generate the plurality of control signals, the plurality of control signal including a first control signal, a second control signal, and a third control signal,
wherein the control signal generation unit includes:
an inverter configured to receive a write enable signal and output an inverted write enable signal;
a first multiplexer configured to receive the write enable signal is and the inverted write enable signal, select either the write enable signal or the inverted write enable signal according to a first test mode signal, and output the first control signal,
a delay configured to receive a data strobe signal and output a delayed data strobe signal,
a second multiplexer configured to receive the data strobe signal and the delayed data strobe signal, select either the data strobe signal or the delayed data strobe signal according to the first test mode signal, and output the second control signal, and
a shift section configured to shift a write command signal by a write latency based on a clock signal, and output the third control signal.

8. The semiconductor apparatus according to claim 1,
wherein the first data processing block comprises:
a read circuit unit configured to perform a read-associated operation for outputting data outputted from the first memory array, to the first input/output pad array, and
a write circuit unit configured to perform a write-associated operation for inputting data inputted through the first input/output pad array, to the first memory array, and
wherein the write circuit unit is configured to receive data outputted via the read circuit unit to the first input/output pad array according to the read command, according to any one among the plurality of control signals, and the write circuit unit is configured to output the received data to the first memory array according to another one among the plurality of control signals.

9. The semiconductor apparatus according to claim 1, wherein the first data processing block comprises:
a buffer configured to receive data outputted via the read circuit unit to the first input/output pad array according to the read command and according to any one among the plurality of control signals; and
an alignment section configured to align and output an output signal of the buffer according to another one among the plurality of control signals.

10. The semiconductor apparatus according to claim 9, wherein the first data processing block further comprises:
an inversion section configured to invert and output an output signal of the alignment section according to a test mode signal.

11. The semiconductor apparatus according to claim 10, wherein the first data processing block further comprises:
a latch section configured to latch and output an output signal of the inversion section in response to an other another one among the plurality of control signals.

12. A semiconductor apparatus comprising:
a first data processing block coupled between a first input/output pad array and a first memory array, and configured to write data outputted from the first memory array, in the first memory array as first test verification data in response to a plurality of control signals during a read operation;
a second data processing block coupled between a second input/output pad array and a second memory array, and configured to write data outputted from the second memory array, in the second memory array as second test verification data in response to the plurality of control signals during the read operation;
a copy unit configured to copy data to be written in the first memory array according to a write command, and write the copied data in the second memory array; and
a comparison unit configured to output a result of comparing the first test verification data and the second test verification data, through the first input/output pad array.

13. The semiconductor apparatus according to claim 12, further comprising:
a storage unit configured to store the result of comparing the first test verification data and the second test verification data.

14. The semiconductor apparatus according to claim 12,
wherein the first data processing block comprises a read circuit unit and a write circuit unit, and
wherein the write circuit unit is configured to receive data outputted to the first input/output pad array via the read circuit unit during the read operation, according to any one among the plurality of control signals, and output the received data to the first memory array according to another one among the plurality of control signals.

15. The semiconductor apparatus according to claim 14,
wherein the plurality of control signals include a first control signal, a second control signal, and a third control signal,
wherein the first control signal of the plurality of control signals is enabled during a write operation period of the semiconductor apparatus,
wherein the second control signal of the plurality of control signals is a signal generated by delaying a data strobe signal by a predetermined time, and
wherein the third control signal is a data input clock signal.

16. The semiconductor apparatus according to claim 12, further comprising:
a control signal generation unit configured to generate the plurality of control signals in response to a write enable signal and a data strobe signal.

17. The semiconductor apparatus according to claim 12, further comprising:
is a control signal generation unit configured to generate any one among the plurality of control signals in response to a test mode signal and a write enable signal, and generate another one among the plurality of control signals in response to the test mode signal and a data strobe signal.

18. The semiconductor apparatus according to claim 1, further comprising:
a control signal generation unit configured to generate the plurality of control signals, the plurality of control signal including a first control signal, a second control signal, and a third control signal,
wherein the control signal generation unit includes:
an inverter configured to receive a write enable signal and output an inverted write enable signal;
a first multiplexer configured to receive the write enable signal and the inverted write enable signal, select either the write enable signal or the inverted write enable signal according to a first test mode signal, and output the first control signal,
a delay configured to receive a data strobe signal and output a delayed data strobe signal,
a second multiplexer configured to receive the data strobe signal and the delayed data strobe signal, select either the data strobe signal or the delayed data strobe signal according to the first test mode signal, and output the second control signal, and
a shift section configured to shift a write command signal by a is write latency based on a clock signal, and output the third control signal.

19. The semiconductor apparatus according to claim 12,
wherein the first data processing block comprises:
a read circuit unit configured to perform a read-associated operation for outputting data outputted from the first memory array to the first input/output pad array, and
a write circuit unit configured to perform a write-associated operation for inputting data inputted through the first input/output pad array to the first memory array, and
wherein the write circuit unit is configured to receive data outputted via the read circuit unit to the first input/output pad array according to a read command, according to any one among the plurality of control signals, and the write circuit unit is configured to output the received data to the first memory array according to another one among the plurality of control signals.

20. The semiconductor apparatus according to claim 12, wherein the first data processing block comprises:
a buffer configured to receive data outputted via the read circuit unit to the first input/output pad array according to the read command and according to any one among the plurality of control signals; and
an alignment section configured to align and output an output signal of the buffer according to another one among the plurality of control signals.

21. The semiconductor apparatus according to claim 20, wherein the first data processing block further comprises:
an inversion section configured to invert and output an output signal of the alignment section according to a test mode signal.

22. The semiconductor apparatus according to claim 12, wherein the first memory array and the second memory array are configured to provide one memory block.

23. The semiconductor apparatus according to claim 22, wherein the first memory array and the second memory array are half banks, respectively.

24. A semiconductor apparatus comprising:
an input/output pad array;
a memory array;
a read circuit unit configured to perform a read-associated operation for outputting data outputted from the memory array, to the input/output pad array in a read operation; and
a write circuit unit configured to perform a write-associated operation for inputting data inputted through the input/output pad array, to the memory array in a write operation, and the write circuit unit is configured to input data outputted to the input/output pad array via the read circuit unit in the read operation, to the memory array according to a plurality of control signals.

25. The semiconductor apparatus according to claim 24, further comprising:
a control signal generation unit configured to generate the plurality of control signals in response to a write enable signal and a data strobe signal.

26. The semiconductor apparatus according to claim 24, further comprising:
a control signal generation unit configured to generate any one among the plurality of control signals in response to a test mode signal and a write enable signal, and generate another one among the plurality of control signals in response to the test mode signal and a data strobe signal.

27. The semiconductor apparatus according to claim 24, further comprising:
a control signal generation unit configured to generate the plurality of control signals, the plurality of control signal including a first control signal, a second control signal, and a third control signal,
wherein the control signal generation unit includes:
an inverter configured to receive a write enable signal and output an inverted write enable signal;
a first multiplexer configured to receive the write enable signal and the inverted write enable signal, select either the write enable signal or the inverted write enable signal according to a first test mode signal, and output the first control signal,
a delay configured to receive a data strobe signal and output a delayed data strobe signal,
a second multiplexer configured to receive the data strobe signal and the delayed data strobe signal, select either the data strobe signal or the delayed data strobe signal according to the first test mode signal, and output the second control signal, and
a shift section configured to shift a write command signal by a write latency based on a clock signal, and output the third control signal.

28. The semiconductor apparatus according to claim 24, wherein the first data processing block comprises:
a buffer configured to receive data outputted via the read circuit unit to the first input/output pad array according to a read command, according to any one among the plurality of control signals;
an alignment section configured to align and output an output signal of the buffer according to another one among the plurality of control signals; and
an inversion block configured to invert and output an output signal of the alignment section according to the test mode signal.

29. The semiconductor apparatus according to claim 24,
wherein the memory array of the semiconductor apparatus includes a first memory array and a second memory array, and
wherein the semiconductor apparatus is configured to copy data to be written in the first memory array according to a write command, and write the copied data in the second memory array.

30. The semiconductor apparatus according to claim 29, wherein the first memory array and the second memory array are configured to provide one memory block.

31. The semiconductor apparatus according to claim 29, wherein the first memory array and the second memory array are half banks, respectively.
